(19) United States
(12) Patent Application Publication
(10) Pub. No.: US 2025/0221005 A1
(43) Pub. Date: Jul. 3, 2025

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: YI-HUAN CHEN, HSINCHU CITY (TW); JHU-MIN SONG, NANTOU COUNTY (TW); CHIEN-CHIH CHOU, NEW TAIPEI CITY (TW); FEI-YUN CHEN, HSINCHU (TW)

(21) Appl. No.: 18/398,203

(22) Filed: Dec. 28, 2023

(51) Int. Cl. H01L 29/423; H01L 29/06; H01L 29/08; H01L 29/66; H01L 29/78

(52) U.S. Cl. CPC H10D 64/518; H10D 30/0227; H10D 30/601; H10D 62/115; H10D 62/151

(57) ABSTRACT

A semiconductor structure includes a first doped region disposed in a substrate, an O-shaped second doped region disposed in the substrate, an O-shaped gate structure disposed over the substrate, an O-shaped first isolation disposed between the O-shaped gate structure and the substrate, a first lightly-doped region in the substrate, and an O-shaped second lightly-doped region in the substrate. The O-shaped second doped region encircles the first doped region. The O-shaped gate structure is disposed between the first doped region and the O-shaped second doped region. The first lightly-doped region is disposed under the first doped region, and the O-shaped second lightly-doped region is disposed under the O-shaped second doped region. The O-shaped gate structure, the O-shaped first isolation, and the O-shaped second lightly-doped region overlap each other to form a first overlaying region.

### BACKGROUND

With ongoing down-scaling of integrated circuits, power supply voltages of the integrated circuits are continuously being reduced. However, such voltage reductions may be different in different circuits or regions. For example, threshold voltage (Vt) requirements of memory circuits may be different from those of core circuits. A multiple-Vt capability is therefore desired for device design.

Multiple-Vt circuits may include high-voltage (HV) devices, middle-voltage (MV) devices and low-voltage (LV) devices. The HV devices, the MV devices and the LV devices may have different requirements. Further, different devices in different applications have various requirements. Manufacturing the multiple Vt circuits therefore is a complicated approach, and many issues arise.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a layout structure of a semiconductor structure in accordance with aspects of the present disclosure in one or more embodiments.

FIG. 1B is a cross-sectional view of a semiconductor structure taken along line I-I′ of FIG. 1A in accordance with aspects of the present disclosure in one or more embodiments.

FIG. 2A is a layout structure of a semiconductor structure in accordance with aspects of the present disclosure in one or more embodiments.

FIG. 2B is a cross-sectional view of a semiconductor structure taken along line II-II′ of FIG. 2A in accordance with aspects of the present disclosure in one or more embodiments.

FIG. 3 is a flowchart representing a method for forming a semiconductor structure in accordance with aspects of the present disclosure.

FIGS. 4 to 12 are cross-sectional views at various stages in the method for forming a semiconductor structure in accordance with aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

Devices operated at multiple voltages are required in many applications, and such devices may face various requirements. For example, an MV device, which may operate at a voltage between 5V and less than tens voltages, may face a noise issue in an analog circuit application. In some comparative approaches, it is found that carriers are trapped at an interface between a gate of the MV device and an isolation that provides electrical isolation for such MV device. The interface-trapped carriers may cause an unwanted noise, which is an issue in the analog circuit.

Therefore, a semiconductor structure and a method of forming the same are provided to mitigate the carrier-trapping issue and thus to mitigate the noise issue in the analog circuit application. According to one embodiment of the present disclosure, a semiconductor structure including an O-shaped gate structure and a method thereof are provided. The O-shaped gate structure of the semiconductor structure is separated from an isolation that provides electrical isolation between the semiconductor structure and adjacent devices. Accordingly, the interface carrier-trapping issue is mitigated, thereby reducing noise in an analog circuit.

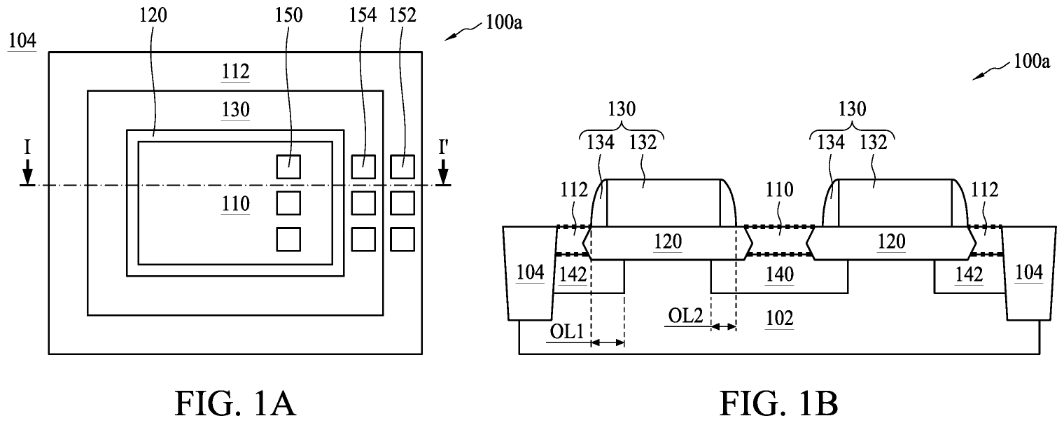

Please refer to FIGS. 1A and 1B, wherein FIG. 1A is a plan view of a layout structure of a semiconductor structure in accordance with aspects of the present disclosure in one or more embodiments, and FIG. 1B is a cross-sectional view taken along line I-I′ of FIG. 1A. Referring to FIGS. 1A and 1B, a semiconductor structure 100a is provided. The semiconductor structure 100a includes a substrate 102. In some embodiments, the substrate 102 may be a semiconductor substrate such as a silicon substrate. The substrate 102 may include other semiconductors material such as germanium (Ge), silicon carbide (SIC), silicon germanium (SiGe), or diamond. Alternatively, the substrate 102 may include a compound semiconductor and/or an alloy semiconductor. The substrate 102 may include various layers, including conductive or insulating layers formed on a semiconductor substrate. The substrate 102 may include various doping configurations depending on design requirements, as is known in the art. For example, different doping profiles (e.g., n wells or p wells) may be formed on the substrate 102 in regions designed for different device types (e.g., n-type field-effect transistors (NFET), or p-type field-effect transistors (PFET)). A suitable doping operation may include ion implantation of dopants and/or diffusion processes.

An isolation 104 is disposed in the substrate 102. In some embodiments, the isolation 104 may be a shallow trench isolation (STI), but the disclosure is not limited thereto. For example, other isolation structures, such as field oxide, local oxidation of silicon (LOCOS), and/or other suitable structures are possible. In some embodiments, the isolation 104 may include silicon oxide (SiO), silicon nitride (SiN), silicon oxynitride (SiON), fluoride-doped silicate glass (FSG), a low-k dielectric material, and/or other suitable insulating materials. In some embodiments, the isolation 104 may be used to define a region accommodating an MV device and to provide electrical isolation between the to-be-formed MV device and other devices.

The semiconductor structure 100a further includes a doped region 110 and an O-shaped doped region 112 disposed in the substrate 102. As shown in FIG. 1A, the O-shaped doped region 112 encircles the doped region 110. In some embodiments, a depth of the doped region 110 and a depth of the O-shaped doped region 112 may be equal, but the disclosure is not limited thereto. The doped region 110 and the O-shaped doped region 112 include dopants of a same doping type. For example, in some embodiments, the doped region 110 and the O-shaped doped region 112 both include n-type dopants, but the disclosure is not limited thereto. In some embodiments, the doped region 110 and the O-shaped doped region 112 each serve as a source/drain region. The source/drain region(s) may refer to a source or a drain, individually or collectively dependent upon the context.

The semiconductor structure 100a further includes an O-shaped isolation 120 disposed over the substrate 102. Further, the O-shaped isolation 120 is disposed between the doped region 110 and the O-shaped doped region 112. In some embodiments, a depth of the O-shaped isolation 120 is greater than the depths of the doped region 110 and the O-shaped doped region 112, as shown in FIG. 1B. Accordingly, the doped region 110 and the O-shaped doped region 112 are entirely separated from each other by the O-shaped isolation 120. In some embodiments, the O-shaped isolation 120 includes field oxide, but the disclosure is not limited thereto.

The semiconductor structure 100a further includes an O-shaped gate structure 130 disposed over the substrate 102. Further, the O-shaped gate structure 130 is disposed between the doped region 110 and the O-shaped doped region 112. The O-shaped gate structure 130 is disposed over the O-shaped isolation 120, and is entirely separated from the substrate 102 by the O-shaped isolation 120. In some embodiments, a portion of the O-shaped isolation 120 is exposed through the O-shaped gate structure 130. For example, a portion of the O-shaped isolation 120 is exposed through an inner edge of the O-shaped gate structure 130, as shown in FIGS. 1A and 1B, but the disclosure is not limited thereto. In some alternative embodiments, a portion of the O-shaped isolation 120 may be exposed through an outer edge of the O-shaped gate structure 130.

In some embodiments, the doped region 110, the O-shaped gate structure 130 and the O-shaped doped region 112 form a symmetric pattern from a top view.

In some embodiments, the O-shaped gate structure 130 includes a gate electrode 132, and the gate electrode 132 may include semiconductor materials or metal materials. In some embodiments, the O-shaped isolation 120 under the gate electrode 132 serves as a gate dielectric layer for the O-shaped gate structure 130. In some embodiments, a sidewall spacer 134 is disposed over the O-shaped isolation 120 and adjacent to sidewalls of the gate electrode 132. In some embodiments, the sidewall spacer 134 is made of silicon nitride (SiN), silicon carbide (SiC), silicon oxide (SiO), silicon oxynitride (SiON), silicon carbide or any other suitable material, but the disclosure is not limited thereto. In some embodiments, sidewalls of the sidewall spacer 134 are entirely in contact with the sidewalls of the gate electrode 132, while a bottom of the sidewall spacer 134 is partially or entirely in contact with the O-shaped isolation 120. In some embodiments, a width of the O-shaped gate structure 130 may be equal to a sum of widths of the bottoms of the sidewall spacer 134 and a width of a bottom of the gate electrode 132. In some embodiments, the width of the O-shaped gate structure 130 is less than a width of the O-shaped isolation 120.

The semiconductor structure 100a further includes a lightly-doped region 140 disposed in the substrate 102 under the doped region 110, and an O-shaped lightly-doped region 142 disposed in the substrate 102 under the O-shaped doped region 112. Therefore, the O-shaped lightly-doped region 142 encircles the lightly-doped region 140. In some embodiments, the O-shaped lightly-doped region 142, the O-shaped doped region 112, the O-shaped gate structure 130, the O-shaped isolation 120, the lightly-doped region 140 and the doped region 110 form a symmetric pattern from the top view. The doped region 110, the O-shaped doped region 112, the lightly-doped region 140 and the O-shaped lightly-doped region 142 include dopants of a same doping type. For example, in some embodiments, the doped region 110, the O-shaped doped region 112, the lightly-doped region 140 and the O-shaped lightly-doped region 142 all include n-type dopants, but the disclosure is not limited thereto. A doping concentration of the lightly-doped region 140 and a doping concentration of the O-shaped lightly-doped region 142 are equal. Further, the doping concentrations of the lightly-doped region 140 and the O-shaped lightly-doped region 142 are less than doping concentrations of the doped region 110 and the O-shaped doped region 112.

Referring to FIG. 1B, a depth of the lightly-doped region 140 and a depth of the O-shaped lightly-doped region 142 are equal. Further, the depth of the lightly-doped region 140 and the depth of the O-shaped lightly-doped region 142 are greater than the depths of the doped region 110 and the O-shape doped region 112. In some embodiments, the depths of the lightly-doped region 140 and the O-shaped lightly-doped region 142 are greater than the depth of the O-shaped isolation 120. Thus, a portion of a bottom of the O-shaped isolation 120 is in contact with the lightly-doped region 140, and another portion of the bottom of the O-shaped isolation 120 is in contact with the O-shaped lightly-doped region 142. In some embodiments, a width of the lightly-doped region 140 is greater than a width of the doped region 110, and a width of the O-shaped lightly-doped region 142 is greater than a width of the O-shaped doped region 112.

Still referring to FIG. 1B, the O-shaped gate structure 130, the O-shaped isolation 120 and the O-shaped lightly-doped region 142 overlap each other to form an overlaying region OL1. In some embodiments, a width of the overlaying region OL1 is between approximately 0 nanometer and approximately 300 nanometers, but the disclosure is not limited thereto. In some embodiments, the O-shaped gate structure 130, the O-shaped isolation 120 and the lightly-doped region 140 overlap each other to form an overlaying region OL2. In some embodiments, a width of the overlaying region OL2 is between approximately 0 nanometer and approximately 300 nanometers, but the disclosure is not limited thereto. In some embodiments, the width of the overlaying region OL2 is equal to the width of the overlaying region OL1. In some alternative embodiments, the width of the overlaying region OL2 is different from the width of the overlaying region OL1. One or both of the overlaying region OL1 and the overlaying region OL2 help to prevent punch-through between the O-shaped doped region 112 and the doped region 110.

In some embodiments, a connecting structure 150 is disposed over the doped region 110, a connecting structure 152 is disposed over the O-shaped doped region 112, and a connecting structure 154 is disposed over the O-shaped gate structure 130. The connecting structures 150, 152 and 154 include a same material. In some embodiments, the connecting structures 150, 152 and 154 may include tantalum (Ta), tantalum nitride (TaN), titanium nitride (TiN), copper (Cu), cobalt (Co), tungsten (W), ruthenium (Ru), aluminum (Al), molybdenum (Mo), iridium (Ir), alloys of the aforementioned materials, or a combination thereof. In some embodiments, the connecting structure 150 is coupled to the doped region 110, and electrically connects the doped region 110 to a metallization layer of a back-end-of-line (BEOL) interconnect structure (not shown). In some embodiments, the connecting structure 152 is coupled to the O-shaped doped region 112, and electrically connects the O-shaped doped region 112 to another metallization layer of the BEOL interconnect structure. In some embodiments, the connecting structure 154 is coupled to the O-shaped gate structure 130, and electrically connects the O-shaped gate structure 130 to another metallization layer of the BEOL interconnect structure. As shown in FIG. 1A, the connecting structures 150, 152 and 154 are configured to form an asymmetric pattern from the top view. In some embodiments, the connecting structures 150, 152 and 154, the O-shaped doped region 112, the O-shaped gate structure 130, the O-shaped isolation 120 and the doped region 110 are configured to form an asymmetric pattern from the top view.

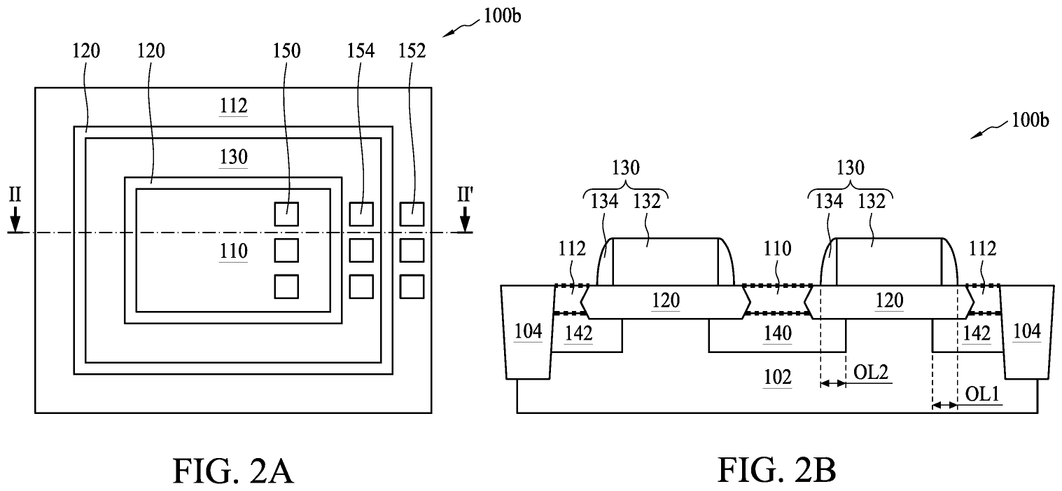

Referring to FIGS. 2A and 2B, FIG. 2A is a plan view of a layout structure of a semiconductor structure in accordance with aspects of the present disclosure in one or more embodiments, and FIG. 2B is a cross-sectional view taken along line II-II′ of FIG. 2A. In some embodiments, a semiconductor structure 100b is provided. The semiconductor device 100b may include same elements as those in semiconductor device 100a; thus, similar elements are depicted by same numerals, and repeated descriptions of such details are omitted for brevity.

Referring to FIGS. 2A and 2B, the semiconductor structure 100b includes a substrate 102. In some embodiments, the substrate 102 may include various doping configurations depending on design requirements, as is known in the art. For example, different doping profiles (e.g., n wells or p wells) may be formed on the substrate 102 in regions designed for different device types (e.g., n-type field-effect transistors (NFET), or p-type field-effect transistors (PFET)). An isolation 104 is disposed in the substrate 102. In some embodiments, the isolation 104 may be an STI, but the disclosure is not limited thereto. In some embodiments, the isolation 104 may be used to define a region accommodating an MV device and to provide electrical isolation between the to-be-formed MV device and other devices.

The semiconductor structure 100b further includes a doped region 110 and an O-shaped doped region 112 disposed in the substrate 102. As shown in FIG. 2A, the O-shaped doped region 112 encircles the doped region 110. In some embodiments, a depth of the doped region 110 and a depth of the O-shaped doped region 112 may be equal. The doped region 110 and the O-shaped doped region 112 include dopants of a same doping type. In some embodiments, the doped region 110 and the O-shaped doped region 112 each serve as a source/drain region.

The semiconductor structure 100b further includes an O-shaped gate structure 130 disposed over the substrate 102. Further, the O-shaped gate structure 130 is disposed between the doped region 110 and the O-shaped doped region 112. The O-shaped gate structure 130 is disposed over an O-shaped isolation 120, and thus the O-shaped gate structure 130 is entirely separated from the substrate 102 by the O-shaped isolation 120. In some embodiments, portions of the O-shaped isolation 120 are exposed through the O-shaped gate structure 130. For example, a portion of the O-shaped isolation 120 is exposed through an inner edge of the O-shaped gate structure 130, and a portion of the O-shaped isolation 120 is exposed through an outer edge of the O-shaped gate structure 130, as shown in FIGS. 2A and 2B.

As mentioned above, the O-shaped gate structure 130 includes a gate electrode 132, and the O-shaped isolation 120 under the gate electrode 132 serves as a gate dielectric layer for the O-shaped gate structure 130. In some embodiments, a sidewall spacer 134 is disposed over the O-shaped isolation 120 and adjacent to sidewalls of the gate electrode 132. In some embodiments, sidewalls of the sidewall spacer 134 are entirely in contact with the sidewalls of the gate electrode 132, while a bottom of the sidewall spacer 134 is partially or entirely in contact with the O-shaped isolation 120. In some embodiments, a width of the O-shaped gate structure 130 may be equal to a sum of widths of the bottoms of the sidewall spacer 134 and a width of a bottom of the gate electrode 132. In some embodiments, the width of the O-shaped gate structure 130 is less than a width of the O-shaped isolation 120.

The semiconductor structure 100b further includes a lightly-doped region 140 disposed in the substrate 102 under the doped region 110, and an O-shaped lightly-doped region 142 disposed in the substrate 102 under the O-shaped doped region 112. Therefore, the O-shaped lightly-doped region 142 encircles the lightly-doped region 140. In some embodiments, the O-shaped lightly-doped region 142, the O-shaped doped region 112, the O-shaped gate structure 130, the O-shaped isolation 120, the lightly-doped region 140 and the doped region 110 form a symmetric pattern from the top view.

Still referring to FIG. 2B, the O-shaped gate structure 130, the O-shaped isolation 120 and the O-shaped lightly-doped region 142 overlap each other to form an overlaying region OL1. In some embodiments, a width of the overlaying region OL1 is between approximately 0 nanometer and approximately 300 nanometers, but the disclosure is not limited thereto. In some embodiments, the O-shaped gate structure 130, the O-shaped isolation 120 and the lightly-doped region 140 overlap each other to form an overlaying region OL2. In some embodiments, a width of the overlaying region OL2 is between approximately 0 nanometer and approximately 300 nanometers, but the disclosure is not limited thereto. In some embodiments, the width of the overlaying region OL2 is equal to the width of the overlaying region OL1. In some alternative embodiments, the width of the overlaying region OL2 is different from the width of the overlaying region OL1. One or both of the overlaying region OL1 and the overlaying region OL2 help to prevent punch-through between the O-shaped doped region 112 and the doped region 110.

In some embodiments, a connecting structure 150 is disposed over the doped region 110, a connecting structure 152 is disposed over the O-shaped doped region 112, and a connecting structure 154 is disposed over the O-shaped gate structure 130. As mentioned above, the connecting structure 150 is coupled to the doped region 110, and electrically connects the doped region 110 to a metallization layer of a BEOL interconnect structure; the connecting structure 152 is coupled to the O-shaped doped region 112, and electrically connects the O-shaped doped region 112 to another metallization layer of the BEOL interconnect structure; and the connecting structure 154 is coupled to the O-shaped gate structure 130, and electrically connects the O-shaped gate structure 130 to another metallization layer of the BEOL interconnect structure. As shown in FIG. 2A, the connecting structures 150, 152 and 154, the O-shaped doped region 112, the O-shaped gate structure 130, the O-shaped isolation 120 and the doped region 110 are configured to form an asymmetric pattern from the top view.

Accordingly, the semiconductor structures 100a and 100b are provided. The semiconductor structures 100a and 100b respectively have the O-shaped gate structure 130 entirely separated from the isolation 104 by the O-shaped doped region 112 and the O-shaped lightly-doped region 142. Therefore, a carrier trapping issue and the consequent noise issue are both mitigated.

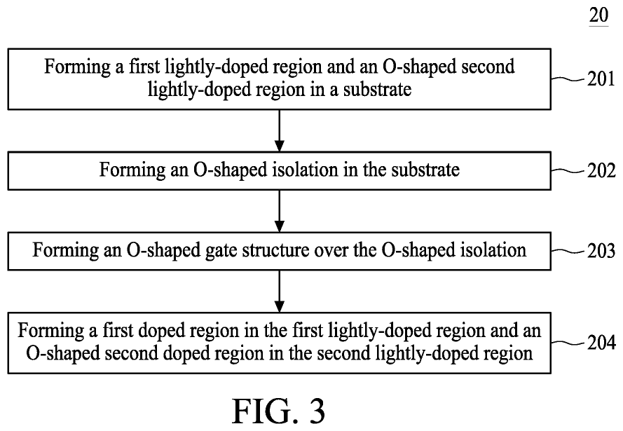

FIG. 3 is a flowchart representing a method for forming a semiconductor structure 20 in accordance with aspects of one or more embodiments of the present disclosure. While the disclosed method 20 is illustrated and described herein as a series of acts or operations, it should be appreciated that an order of the illustrated acts or operations is not intended to be interpreted in a limiting sense. For example, some operations may be performed in a different order and/or concurrently with other acts or operations apart from those illustrated and/or described herein. In addition, not all illustrated operations may be required to implement one or more aspects or embodiments of the invention described herein. Further, one or more of the operations described herein may be carried out in one or more separate operations and/or phases.

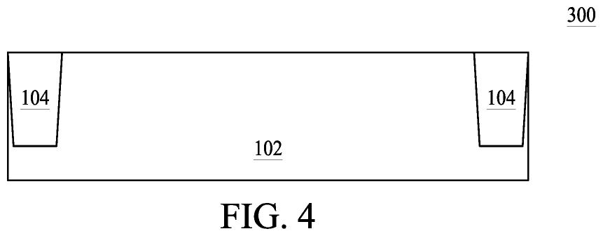

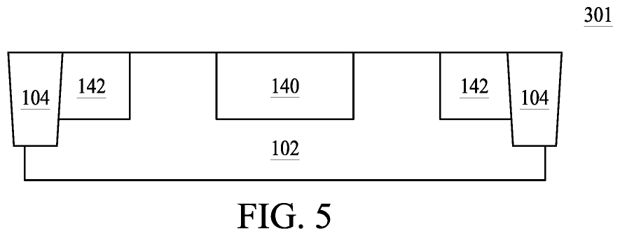

In operation 201, a lightly-doped region 140 and an O-shaped lightly-doped region 142 are formed over a substrate 102. FIGS. 4 and 5 are cross-sectional views of intermediate semiconductor structures 300 and 301 according to some embodiments corresponding to operation 201. In some embodiments, the operation 201 may include further steps. For example, as shown in FIG. 4, a substrate 102 is received, and an isolation 104 is formed in the substrate 102. As mentioned above, the isolation 104 is formed in the substrate 102 to define a region where a device, such as an MV device, is to be subsequently formed, and the isolation 104 is also formed to provide electrical isolation between the to-be-formed MV device and other devices or elements.

Referring to FIG. 5, the lightly-doped region 140 and the O-shaped lightly-doped region 142 are formed in the substrate 102. Further, the lightly-doped region 140 and the O-shaped lightly-doped region 142 are formed within the region defined by the isolation 104. In some embodiments, the lightly-doped region 140 and the O-shaped lightly-doped region 142 are simultaneously formed by suitable photolithography and ion implantation operations. The O-shaped lightly-doped region 142 encircles the lightly-doped region 140. As mentioned above, the lightly-doped region 140 and the O-shaped lightly-doped region 142 include dopants of a same doping type. A doping concentration of the lightly-doped region 140 is equal to a doping concentration of the O-shaped lightly-doped region 142. Further, a depth of the lightly-doped region 140 is equal to a depth of the O-shaped lightly-doped region 142.

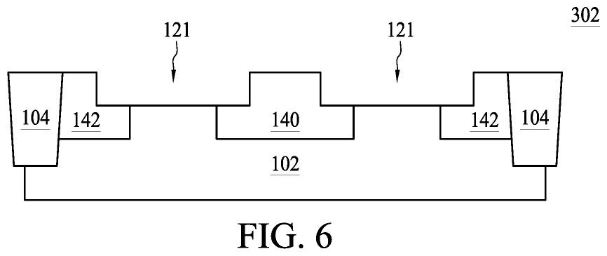

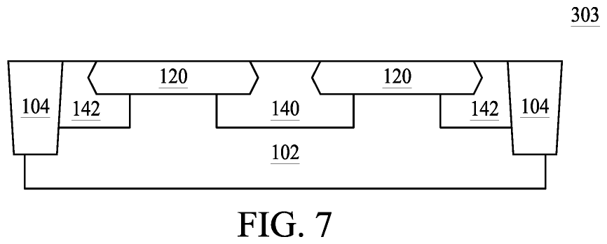

In operation 202, an O-shaped isolation 120 is formed in the substrate 102. FIGS. 6 and 7 are cross-sectional views of intermediate semiconductor structures 302 and 303 according to some embodiments corresponding to operation 202. In some embodiments, the operation 202 may include further steps. For example, an O-shaped recess 121 may be formed in the substrate 102. In some embodiments, a depth of the O-shaped recess 121 is less than the depth of the lightly-doped region 140, and less than the depth of the O-shaped lightly-doped region 142. In some embodiments, the depth of the O-shaped recess 121 is between approximately 100 angstroms and approximately 300 angstroms, but the disclosure is not limited thereto. Further, portions of the lightly-doped region 140, portions of the O-shaped lightly-doped region 142 and portions of the substrate 102 are exposed through the O-shaped recess 121. As shown in FIG. 6, a portion of the lightly-doped region 140, a portion of the substrate 102, and a portion of the O-shaped lightly-doped region 142 are exposed though a bottom of the O-shaped recess 121. Further, a portion of the lightly-doped region 140 and a portion of the O-shaped lightly-doped region 142 are exposed though sidewalls of the O-shaped recess 121.

Referring to FIG. 7, in some embodiments, the O-shaped recess 121 is filled with insulating material to form the O-shaped isolation 120. In some embodiments, the O-shaped isolation 120 may include field oxide, but the disclosure is not limited thereto. A top surface of the O-shaped isolation 120 may be coplanar or level with a top surface of the substrate 102, but the disclosure is not limited thereto. For example, in some embodiments, the top surface of the O-shaped isolation 120 may be higher than the top surface of the substrate 102. As shown in FIG. 7, in some embodiments, the O-shaped isolation 120 overlaps a portion of the lightly-doped region 140, a portion of the O-shaped lightly-doped region 142 and a portion of the substrate 102. In some embodiments, a bottom surface of the O-shaped isolation 120 is in contact with the lightly-doped region 140, the substrate 102 and the O-shaped lightly-doped region 142. Further, an inner sidewall of the O-shaped isolation 120 is in contact with the lightly-doped region 140, while an outer sidewall of the O-shaped isolation 120 is in contact with the O-shaped lightly-doped region 142.

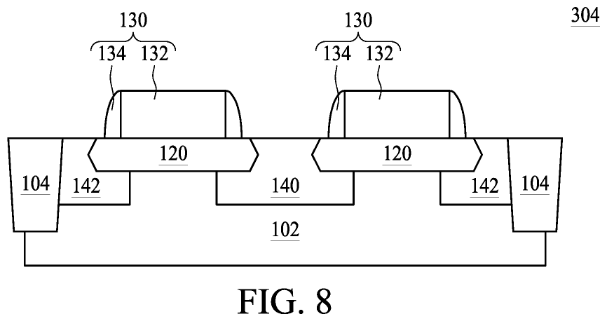

In operation 203, an O-shaped gate structure 130 is formed over the O-shaped isolation 120. Please refer to FIG. 8, which is a cross-sectional view of an intermediate semiconductor structure 304 according to some embodiments corresponding to operation 203. In some embodiments, a semiconductor layer is formed and patterned to form an O-shaped gate electrode 132 over the O-shaped isolation 120. A sidewall spacer 134 is then formed over sidewalls of the O-shaped gate electrode 132, thereby forming the O-shaped gate structure 130. In some embodiments, the sidewall spacer 134 is formed by deposition and etch-back operations. A width of the O-shaped gate structure 130 is less than a width of the O-shaped isolation 120. In some embodiments, a portion of the O-shaped isolation 120 may therefore be exposed through an inner edge or an outer edge of the O-shaped gate structure 130. In other embodiments, portions of the O-shaped isolation 120 are exposed though both the inner edge and the outer edge of the O-shaped gate structure 130, as shown in FIG. 8. In some embodiments, the O-shaped gate structure 130 is separated from the substrate 102 by the O-shaped isolation 120. Further, the gate electrode 132 is entirely separated from the substrate 102 by the O-shaped isolation 120. Additionally, the O-shaped isolation 120 may serve as a gate dielectric layer for a to-be-formed MV device.

As shown in FIG. 8, the O-shaped gate structure 130, which is formed after the forming of the lightly-doped region 140 and the O-shaped lightly-doped region 142, is entirely separated from the isolation 104 by, at least, the O-shaped lightly-doped region 142.

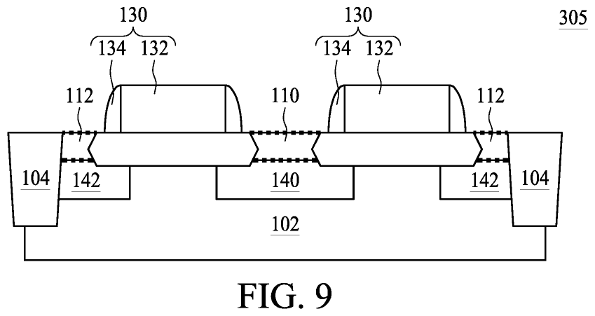

In operation 204, a doped region 110 is formed in the lightly-doped region 140, and an O-shaped doped region 112 is formed in the O-shaped lightly-doped region 142. Please refer to FIG. 9, which is a cross-sectional view of an intermediate semiconductor structure 305 according to some embodiments corresponding to operation 204. The doped region 110 and the O-shaped doped region 112 are simultaneously formed by suitable photolithography and ion implantation operations. The doped region 110, the O-shaped doped region 112, the lightly-doped region 140, and the O-shaped lightly-doped region 142 include dopants of a same doping type. Doping concentrations of the doped region 110 and the O-shaped doped region 112 are greater than the doping concentrations of the lightly-doped region 140 and the O-shaped lightly-doped region 142. Depths of the doped region 110 and the O-shaped doped region 112 are less than the depths of lightly-doped region 140 and the O-shaped lightly-doped region 142. As mentioned above, the doped region 110 and the O-shaped doped region 112 function as source/drain regions.

Accordingly, a field-effect transistor (FET) device including the O-shaped gate structure 130, the lightly-doped region 140, the doped region 110, the O-shaped lightly-doped region 142 and the O-shaped doped region 112 is obtained. In some embodiments, the FET device is an MV device, but the disclosure is not limited thereto. Additionally, the O-shaped gate structure 130 is entirely separated from the isolation 104 by the O-shaped lightly-doped region 142 and the O-shaped doped region 112.

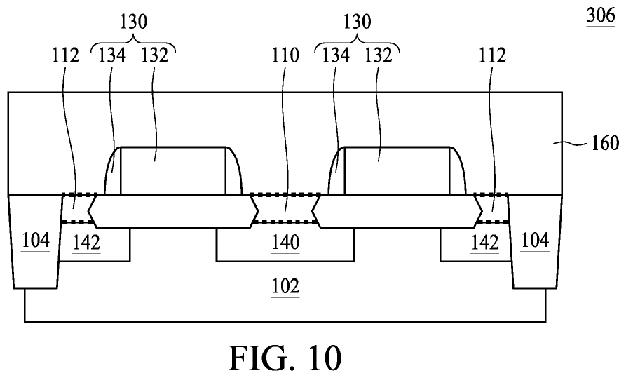

In some embodiments, after the forming of the doped region 110 and the O-shaped doped region 112, also referred to as the source/drain regions, further operations are performed. Please refer to FIG. 10, which is a cross-sectional view of an intermediate semiconductor structure 306 according to some embodiments subsequent to operation 204. In some embodiments, a dielectric structure 160 is formed over the substrate 102. The dielectric structure 160 may include a contact etch stop layer (CESL) and an interlayer dielectric (ILD) layer, though not shown. In some embodiments, the CESL can include silicon nitride, silicon oxynitride, and/or other applicable materials. The ILD structure may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon-doped silicon oxide, amorphous fluorinated carbon, parylene, bis-benzocyclobutenes (BCB), and polyimide.

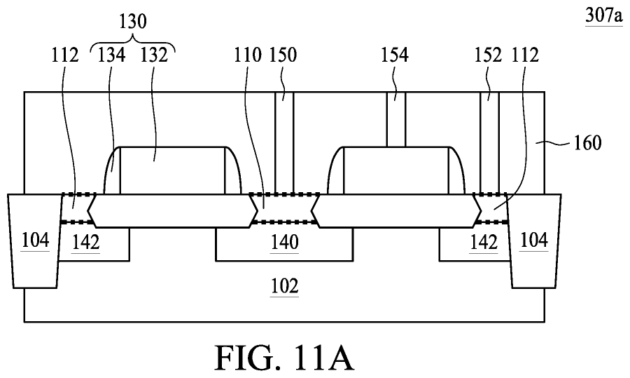

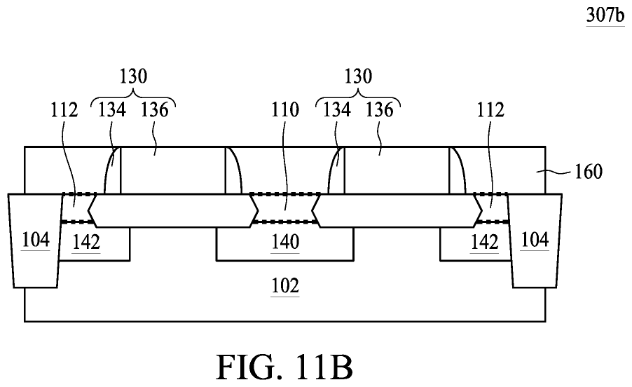

Referring to FIG. 11A, which is a cross-sectional view of an intermediate semiconductor structure 307a according to some embodiments subsequent to operation 204, a plurality of connecting structures are formed. In some embodiments, the forming of the connecting structures includes, at least, forming openings in dielectric structure 160. In some embodiments, a portion of the doped region 110, a portion of the O-shaped doped region 112 and a portion of the O-shaped gate structure 130 may be exposed through corresponding openings. Salicide structures may be formed over the portions of the doped region 110, the O-shaped doped region 112 and the O-shaped gate structure 130 exposed through the openings. Conductive materials are then formed to fill the openings, followed by a planarization. In some embodiments, the connecting structures include a connecting structure 150 coupled to the doped region 110, a connecting structure 152 coupled to the O-shaped doped region 112, and a connecting structure 154 coupled to the O-shaped gate structure 130, as shown in FIG. 11A. As mentioned above, the connecting structures 150, 152 and 154 help to provide electrical connections between the FET device (i.e., the doped regions 110, the O-shaped doped region 112 and the O-shaped gate structure 130 of the FET device) and metallization layers of a BEOL interconnect structure.

Please refer to FIG. 11B, which is a cross-sectional view of an intermediate semiconductor structure 307b according to some embodiments subsequent to operation 204. In some embodiments, a portion of the dielectric structure 160 is removed to expose a top surface of the O-shaped gate structure 130. In such embodiments, the gate electrode 132 is used as a sacrificial gate in a replacement gate (RPG) approach.

Subsequently, a gate trench (not shown) is formed by removing the sacrificial gate. In some embodiments, a high-k dielectric layer (not shown) may be formed in the gate trench. A work function metal layer and a gap-filling metal layer are then formed in the gate trench, though both not shown. The work function metal layer may be formed by CVD, PVD and/or other suitable processes. The gap-filling metal layer may include metal materials having low resistance, and may be formed by CVD, PVC, plating and/or other suitable processes. Further, a planarization is performed to remove superfluous layers, thereby forming a metal gate electrode 136. In some embodiments, the metal gate electrode 136 and the sidewall spacer 134 are referred to as the O-shaped gate structure 130.

Accordingly, a FET device including the O-shaped gate structure 130, the doped region 110, the O-shaped doped region 112, the lightly-doped region 140 and the O-shaped lightly-doped region 142 is obtained. In some embodiments, the FET device is an MV device, but the disclosure is not limited thereto. Additionally, the O-shaped gate structure 130 is entirely separated from the isolation 104 by the O-shaped lightly-doped region 142 and the O-shaped doped region 112.

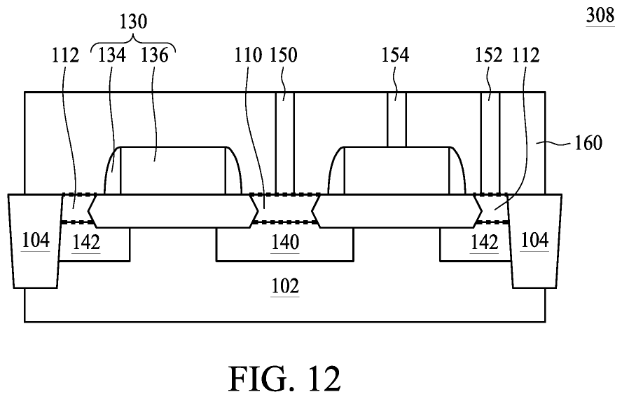

Referring to FIG. 12, which is a cross-sectional view of an intermediate semiconductor structure 308 according to some embodiments subsequent to operation 204, a plurality of connecting structures are formed. In some embodiments, a dielectric layer (not shown) may be formed over the dielectric structure 160, followed by the forming of the connecting structures. In some embodiments, the forming of the connecting structures may be similar to the forming of the connecting structures described above; therefore, those details are omitted. In some embodiments, the connecting structures include a connecting structure 150 coupled to the doped region 110, a connecting structure 152 coupled to the O-shaped doped region 112, and a connecting structure 154 coupled to the O-shaped gate structure 130, as shown in FIG. 12. As mentioned above, the connecting structures 150, 152 and 154 help to provide electrical connections between the FET device (i.e., the doped regions 110, the O-shaped doped region 112 and the O-shaped gate structure 130) and metallization layers of a BEOL interconnect structure.

According to the method for forming the semiconductor structure 20, the O-shaped gate structure 130 is formed after the forming of the O-shaped lightly-doped region 142 and the lightly-doped region 140. Further, the O-shaped gate structure 130 is entirely separated from the isolation 104 by the O-shaped lightly-doped region 142 and the O-shaped doped region 112. Thus, the carrier trapping issue is mitigated. Consequently, the noise issue in analog circuits is also mitigated. Further, the provided method 20 can be performed to form a FET device including a semiconductor gate structure, and to form a FET device including metal gate structure. Thus, process practicality and flexibility are improved.

According to one embodiment of the present disclosure, a semiconductor structure is provided. The semiconductor structure includes a first doped region disposed in a substrate, an O-shaped second doped region disposed in the substrate, an O-shaped gate structure disposed over the substrate, an O-shaped first isolation disposed between the O-shaped gate structure and the substrate, a first lightly-doped region in the substrate, and an O-shaped second lightly-doped region in the substrate. The O-shaped second doped region encircles the first doped region. The O-shaped gate structure is disposed between the first doped region and the O-shaped second doped region. The first lightly-doped region is disposed under the first doped region, and the O-shaped second lightly-doped region is disposed under the O-shaped second doped region. The O-shaped gate structure, the O-shaped first isolation, and the O-shaped second lightly-doped region overlap each other to form a first overlaying region.

According to one embodiment of the present disclosure, a semiconductor structure is provided. The semiconductor structure includes a first doped region disposed in a substrate, an O-shaped second doped region disposed in the substrate, an O-shaped gate structure disposed over the substrate, a first connecting structure disposed over the first doped region, a second connecting structure disposed over the O-shaped second doped region, and a third connecting structure disposed over the O-shaped gate structure. The O-shaped second doped region encircles the first doped region. The O-shaped gate structure is disposed between the first doped region and the O-shaped second doped region. The first connecting structure, the second connecting structure and the third connecting structure form an asymmetric pattern from a top view.

According to one embodiment of the present disclosure, a method for forming a semiconductor structure is provided. The method includes following operations. A first lightly-doped region and an O-shaped second lightly-doped region are formed in a substrate. The O-shaped second lightly-doped region encircles the first lightly-doped region. An O-shaped isolation is formed over the substrate. The O-shaped isolation overlaps a portion of the first lightly-doped region, a portion of the O-shaped second lightly-doped region and a portion of the substrate. An O-shaped gate structure is formed over the O-shaped isolation. A first doped region is formed in the first lightly-doped region, and an O-shaped second doped region is formed in the O-shaped second lightly-doped region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a first doped region disposed in a substrate;
an O-shaped second doped region disposed in the substrate and encircling the first doped region;
an O-shaped gate structure disposed over the substrate and between the first doped region and the O-shaped second doped region;
an O-shaped first isolation disposed between the substrate and the O-shaped gate structure;
a first lightly-doped region disposed in the substrate and under the first doped region; and
an O-shaped second lightly-doped region disposed in the substrate and under the O-shaped second doped region,
wherein the O-shaped gate structure, the O-shaped first isolation and the O-shaped second lightly-doped region overlap each other to form a first overlaying region.

2. The semiconductor structure of claim 1, wherein the first doped region, the O-shaped second doped region, the first lightly-doped region and the O-shaped second lightly-doped region comprise a same doping type.

3. The semiconductor structure of claim 1, wherein the O-shaped first isolation is partially exposed an outer edge and/or an inner edge of the O-shaped gate structure.

4. The semiconductor structure of claim 1, wherein the O-shaped gate structure, the O-shaped first isolation and the first doped region overlap each other to form a second overlaying region.

5. The semiconductor structure of claim 4, wherein a width of the first overlaying region is equal to a width of the second overlaying region.

6. The semiconductor structure of claim 4, wherein a width of the first overlaying region is different from a width of the second overlaying region.

7. The semiconductor structure of claim 1, further comprising a second isolation encircling the O-shaped second doped region, wherein the O-shaped gate structure is entirely separated from the second isolation by the O-shaped second doped region.

8. The semiconductor structure of claim 1, further comprising:
a first connecting structure disposed over the first doped region;
a second connecting structure disposed over the O-shaped second doped region; and
a third connecting structure disposed over the O-shaped gate structure.

9. The semiconductor structure of claim 8, wherein the first connecting structure, the second connecting structure and the third connecting structure form an asymmetric pattern from a top view.

10. A semiconductor structure comprising:
a first doped region disposed in a substrate;
an O-shaped second doped region disposed in the substrate and encircling the first doped region;
an O-shaped gate structure disposed over the substrate and between the first doped region and the O-shaped second doped region;
a first connecting structure disposed over the first doped region;
a second connecting structure disposed over the O-shaped second doped region; and
a third connecting structure disposed over the O-shaped gate structure,
wherein the first connecting structure, the second connecting structure and the third connecting structure form an asymmetric pattern from a top view.

11. The semiconductor structure of claim 10, wherein the first doped region, the O-shaped gate structure and the O-shaped second doped region form a symmetric pattern from the top view.

12. The semiconductor structure of claim 10, further comprising an O-shaped isolation disposed between the O-shaped gate structure and the substrate.

13. The semiconductor structure of claim 12, wherein the O-shaped isolation is partially exposed through an outer edge or an inner edge of the O-shaped gate structure.

14. The semiconductor structure of claim 12, wherein the O-shaped isolation is partially exposed through an outer edge and an inner edge of the O-shaped gate structure.

15. A method for forming a semiconductor structure, comprising:
forming a first lightly-doped region and an O-shaped second lightly-doped region in a substrate, wherein the O-shaped second lightly-doped region encircles the first lightly-doped region;
forming an O-shaped isolation overlapping a portion of the first lightly-doped region, a portion of the O-shaped second lightly-doped region and a portion of the substrate;
forming an O-shaped gate structure over the O-shaped isolation; and
forming a first doped region in the first lightly-doped region and an O-shaped second doped region in the O-shaped second lightly-doped region.

16. The method of claim 15, wherein the first lightly-doped region, the O-shaped second lightly-doped region, the first doped region and the O-shaped second doped region comprise a same doping type.

17. The method of claim 15, wherein the forming of the first lightly-doped region and the O-shaped second lightly-doped region is performed prior to the forming of the O-shaped gate structure.

18. The method of claim 15, wherein the forming of the O-shaped isolation further comprises:
forming an O-shaped recess in the substrate; and
filling the O-shaped recess with an insulating material.

19. The method of claim 18, wherein a depth of the O-shaped recess is less than a depth of the first lightly-doped region, and less than a depth of the O-shaped second lightly-doped region.

20. The method of claim 15, further comprising forming an O-shaped metal gate structure after the forming of the first doped region and the O-shaped second doped region.
